(19) United States
(12) Patent Application Publication
(10) Pub. No.: US 2026/0223678 A1
(43) Pub. Date: Jul. 30, 2026

(54) SEMICONDUCTOR DEVICE WITH A SENSOR DEVICE

(71) Applicant: Infineon Technologies Dresden AG & Co. KG, Dresden (DE)

(72) Inventors: Tillmann Walther, Dresden (DE); Matthias Fiebig, München (DE); Matteo Dainese, München (DE)

(21) Appl. No.: 19/457,977

(22) Filed: Jan. 23, 2026

(30) Foreign Application Priority Data
Jan. 27, 2025 (DE) 102025102764.1

(51) Int. Cl. H10W 40/50; H10D 12/00; H10D 30/66

(52) U.S. Cl. CPC H10W 40/50; H10D 12/481; H10D 30/668

(57) ABSTRACT

A semiconductor includes a semiconductor substrate and an active cell region that includes a plurality of active cell trenches extending from a first main surface of the semiconductor substrate into the semiconductor substrate. The semiconductor device further includes a sensor region having a sensor device and a sensor pad formed over the first main surface of the semiconductor substrate and electrically connected to a first terminal of the sensor device. A semiconductor substrate region of the semiconductor substrate is formed below the sensor pad. A plurality of capacitance trenches is formed below the sensor pad and extends from the first main surface of the semiconductor substrate into or through the semiconductor substrate region. One of a capacitance electrode formed in one of the plurality of capacitance trenches or the semiconductor substrate region is electrically connected to the sensor pad and forms a first electrode of an input capacitance.

### TECHNICAL FIELD

The present disclosure relates to a semiconductor device with an active cell region and a sensor region including a sensor device.

### BACKGROUND

For semiconductor devices, an ESD (electrostatic discharge) ruggedness test is a ‘charge injection’ stress test whereby a certain amount of electric charge is forced into an electrical access point to the device. ESD ruggedness is one of the defining SOA (safe operating area) specifications of a semiconductor device. Typical ESD ruggedness verification is executed according to the HBM (human body model) ESD specification, whereby a capacitor of 100pF, charged up to a certain voltage, is discharged over an electrical contact of the chip, through a 1.5kOhm resistor. There is a need for semiconductor devices with improved ESD ruggedness.

### SUMMARY

According to an embodiment of a semiconductor device, the semiconductor device comprises a semiconductor substrate and an active cell region that comprises a plurality of active cell trenches extending from a first main surface of the semiconductor substrate into the semiconductor substrate. The semiconductor device further comprises a sensor region comprising a sensor device and a sensor pad formed over the first main surface of the semiconductor substrate and electrically connected to a first terminal of the sensor device. A semiconductor substrate region of the semiconductor substrate is formed below the sensor pad. A plurality of capacitance trenches is formed below the sensor pad and extends from the first main surface of the semiconductor substrate into or through the semiconductor substrate region. One of a capacitance electrode formed in one of the plurality of capacitance trenches or the semiconductor substrate region is electrically connected to the sensor pad and forms a first electrode of an input capacitance.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates a partial top view of an exemplary semiconductor device;

FIG. 2 schematically illustrates a cross-sectional view of the semiconductor device along a line labelled B-B’ in FIG. 1;

FIGS. 3A to 3D schematically illustrate cross-sectional views of the semiconductor device along a line labelled A-A’ in FIG. 1;

FIG. 4 schematically illustrates a partial top view of a further exemplary semiconductor device;

FIG. 5 illustrates a circuit schematic of an implementation of a current sensor transistor and a main transistor as described in connection with FIG. 4;

FIGS. 6A and 6B schematically illustrate partial top views of a transition region that is arranged at an interface between a region below a sensor pad and an active cell region;

FIG. 7A schematically illustrates a top view of an implementation of a semiconductor substrate region below a sensor pad;

FIG. 7B schematically illustrates an enlarged top view of an implementation of an interface region;

FIG. 8 schematically illustrates a partial top view of a further exemplary semiconductor device;

FIG. 9 illustrates a circuit schematic of an implementation of a temperature sensor device and a main transistor; and

FIG. 10 schematically illustrates a cross-sectional view of the semiconductor device along a line labelled C-C’ in FIG. 8.

### DETAILED DESCRIPTION

The making and using of several examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention.

The terms "having", "containing", "including", "comprising" and the like are open ended terms that indicate the presence of stated structures, elements or features but do not preclude the presence of additional elements or features. The articles "a", "an" and "the" are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

The terms “bonded”, “attached”, “connected” and/or “coupled” are not meant to mean that the elements or layers must directly be contacted together; intervening elements or layers may be provided between the “bonded”, “attached”, “connected” and/or “coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected” and/or “coupled” elements, respectively.

The term "electrically connected" describes a permanent low-resistive connection between electrically connected elements, for example a direct contact between the concerned elements or a low-resistive connection via a metal and/or heavily doped semiconductor material.

The terms "on" and “over” are not to be construed as meaning only "directly on" and “directly over”. Rather, if one element is positioned "on" or “over” another element (e. g., a layer is "on" or “over” another layer or "on" or “over” a substrate), a further component (e. g., a further layer) may be positioned between the two elements (e. g., a further layer may be positioned between a layer and a substrate if the layer is "on" or “over” said substrate).

Spatially relative terms, such as “beneath,” “below,” “lower,” “above,” “upper”, “under”, “over” and the like, are used herein for ease of description to explain the positioning of one element relative to another element. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Described next, with reference to the figures, are exemplary implementations of a semiconductor device. While the exemplary implementations are described in the context of IGBT (insulated gate bipolar transistor) devices, the exemplary implementations may be realized using other types of transistors such as MOSFET (metal-oxide-semiconductor field-effect transistor) devices, BJT (bipolar junction transistor) devices, JFET (junction field-effect transistor) devices, etc. That means, references to emitter and collector may apply equally to source and drain of a MOSFET, or similar terminals of other types of transistors. That means, when the following refers to an emitter, this also means a source (source/emitter). And when the following refers to a collector, this also means a drain (drain/collector). In the following implementations, the first conductivity type is n-type and the second conductivity type is p-type for an n-channel device whereas the first conductivity type is p-type and the second conductivity type is n-type for a p-channel device.

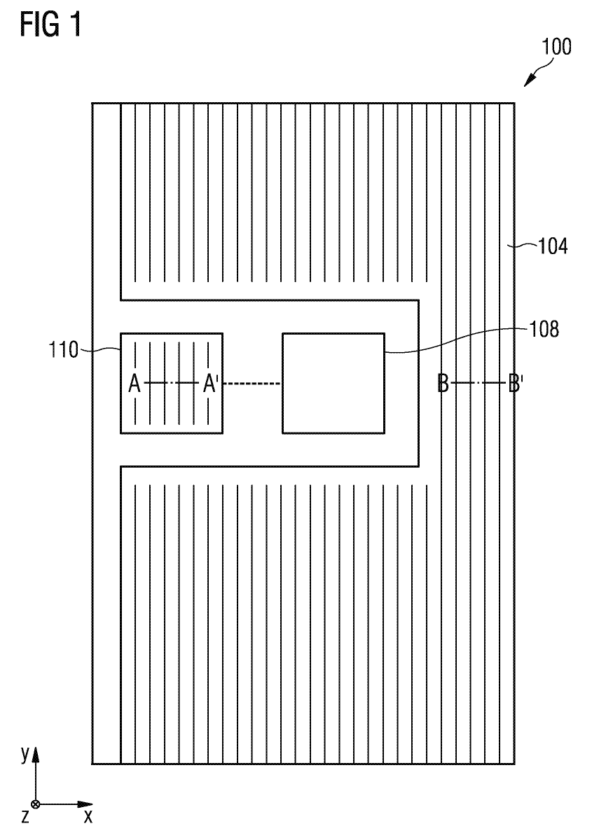

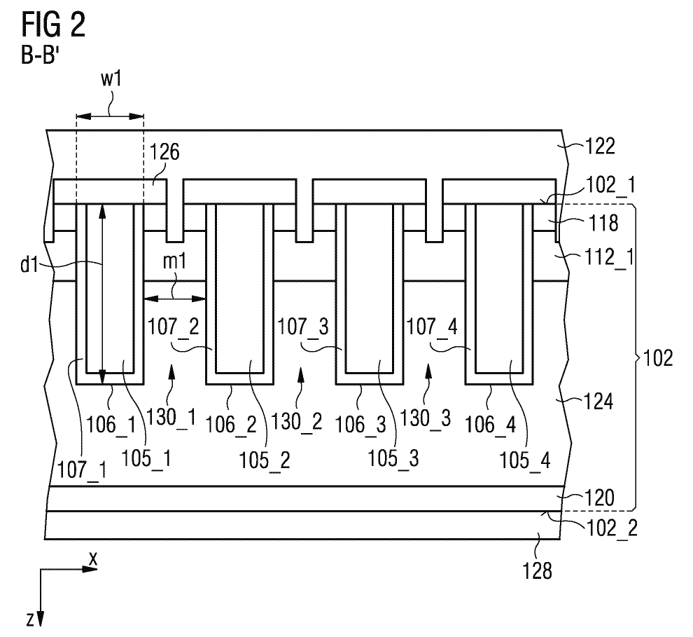

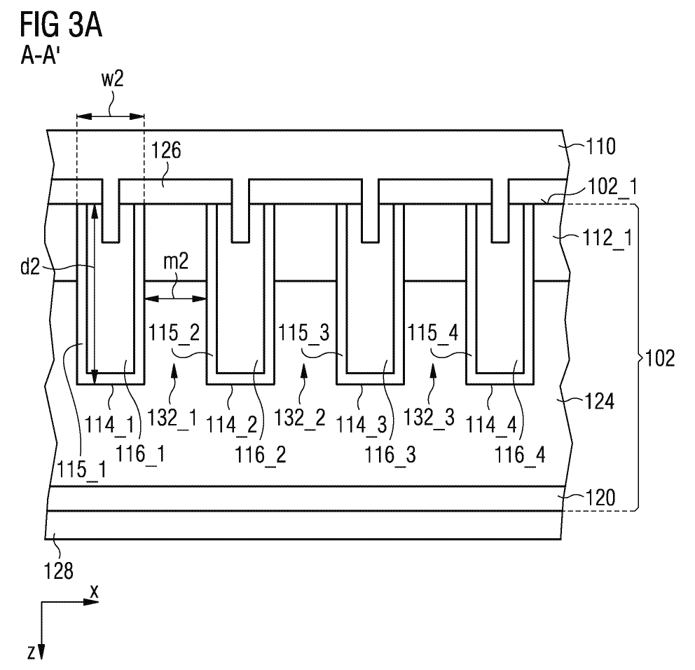

FIG. 1 schematically illustrates a partial top view of an exemplary semiconductor device 100. FIG. 2 schematically illustrates a cross-sectional view of the semiconductor device 100 along the line labelled B-B’ in FIG. 1. FIGS. 3A to 3D schematically illustrate cross-sectional views of the semiconductor device 100 along the line labelled A-A’ in FIG. 1. It is noted that FIG. 1 contains less details than FIG. 2 and FIGS. 3A to 3D for ease of illustration and to provide an unobstructed view.

The semiconductor device 100 includes a semiconductor substrate 102. The semiconductor substrate 102 may include one or more of a variety of semiconductor materials that are used to form semiconductor devices. For example, the semiconductor substrate 102 may include single element semiconductors (e. g. Si, Ge, etc.), silicon-on-insulator semiconductors, binary semiconductors (e. g. SiC, GaN, GaAs, SiGe, etc.), ternary semiconductors (e. g. AlGaN, InGaAs, InAlAs, etc.). The semiconductor substrate 102 may be a bulk semiconductor material or may include one or more additional elements, like e. g., epitaxial layers grown on a bulk semiconductor material, field stop regions, buffer layers, well regions, highly/lowly doped regions, etc. The bulk semiconductor material may be referred to as base semiconductor. The semiconductor substrate 102 has a first main surface 102_1 and a second main surface 102_2 opposite the first main surface 102_1. The first main surface 102_1 may be referred to as front surface and the second main surface 102_2 may be referred to as back surface.

The semiconductor device 100 further includes an active cell region 104 and a sensor region 108. The active cell region 104 includes a plurality of active cells that are electrically coupled in parallel to form a power transistor of the semiconductor device 100. The power transistor may be referred to as main transistor.

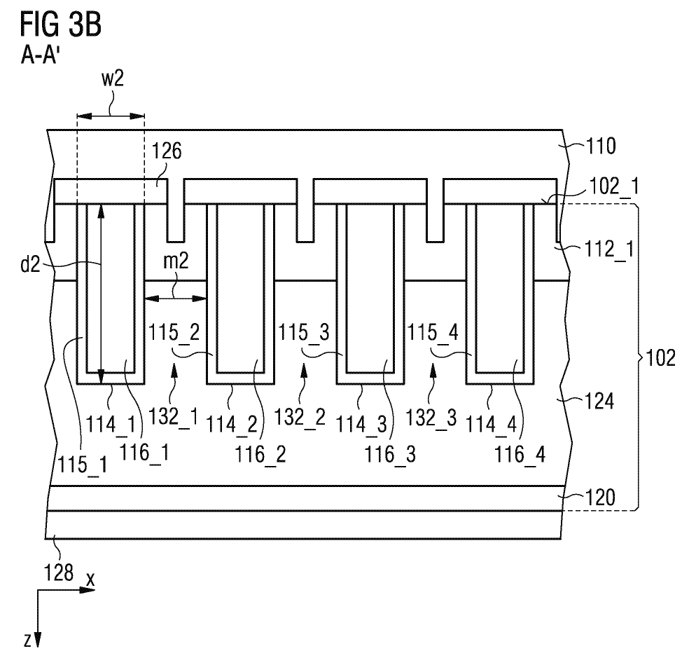

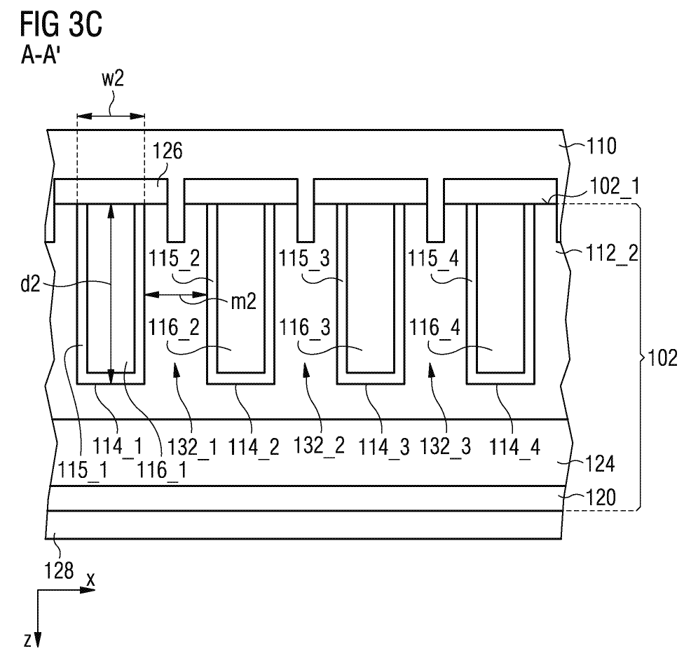

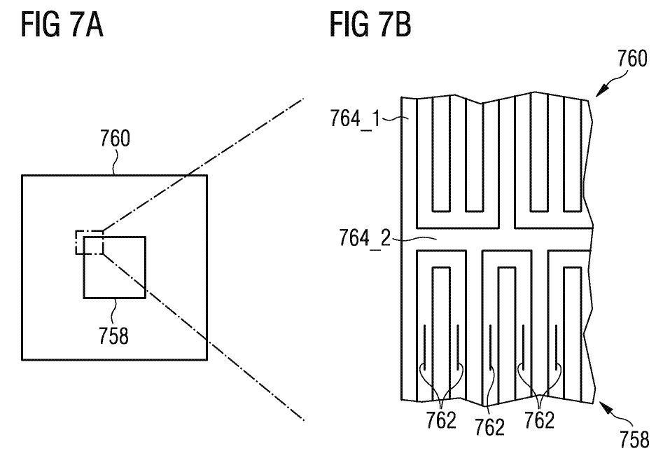

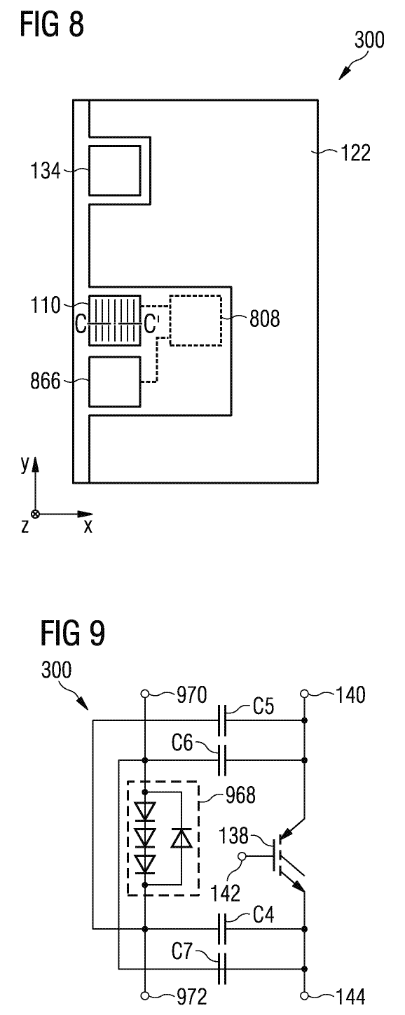

The sensor region 108 includes a sensor device that is configured to sense a parameter of the semiconductor device 100. In one example, the sensor device is a temperature sensor device that is configured to allow for a measurement of a temperature of the semiconductor device 100 as will be described in more detail in connection with FIG. 8 and FIG. 9 below. In another example, the sensor device is a current sensor device that is configured to allow for a measurement of a current in the sensor region 108 as will be described in more detail in connection with FIG. 4 and FIG. 5 below.

The semiconductor device 100 further includes a sensor pad 110 that is formed over the first main surface 102_1 of the semiconductor substrate 102. The sensor pad 110 is electrically connected to a first terminal of the sensor device as indicated by a dotted line in FIG. 1. Due to its configuration, the sensor device is susceptible to damage caused by an ESD (Electrostatic Discharge) event that is received at the sensor pad 110.

The semiconductor device 100 further includes a structure that is formed below the sensor pad 110 to increase the capacitance between the sensor pad 110 and other load/control pads of the semiconductor device 100. This structure enhances the ability of the semiconductor device 100 to store charges and therefore, peak electric fields in case of an ESD event can be reduced. That means, the ESD robustness of the sensor device and therefore also of the semiconductor device 100 is improved. The structure may be referred to as ESD capacitance, added/additional input capacitance or support capacitance. Especially the input capacitance of the sensor region 108 is increased largely by adding more capacity between the sensor terminal and all other device terminals which increases the ESD ruggedness of the sensor device. As the sensor device is the weakest ESD part of the semiconductor device 100, the overall device ESD ruggedness is improved. Those added capacitances may reduce or eliminate oscillations of a sensor signal by either damping or shifting resonance frequencies.

In the schematically illustrated example of FIG. 1, the active cell region 104 comprises a plurality of active cell trenches. Besides, a plurality of capacitance trenches are formed in a vertical direction z below the sensor pad 110. In the example of FIG. 1, the plurality of active cell trenches and the plurality of capacitance trenches are stripe-shaped trenches that extend in parallel along a first lateral direction y parallel to the first main surface 102_1 of the semiconductor substrate 102. In other examples, the trenches may have a different shape than stripes arranged in parallel. For example, the trenches may have any type of shape, for example, an open shape such as straight stripe or, for example, a closed shape such as a grid shape. The grid may be a rectangular, a square, a hexagonal or an octagonal grid. The plurality of active cell trenches may be a plurality of active cell trench segments that are linked to each other or that merge into one another to form a contiguous active cell trench structure. Similarly, the plurality of capacitance trenches may be a plurality of capacitance trench segments that are linked to each other or that merge into one another to form a contiguous capacitance trench structure. In one example, the active cell trenches may have a different shape than the capacitance trenches.

In the schematically illustrated example of FIG. 1, the sensor pad 110 is arranged separately from the sensor region 108. That means, the sensor pad 110 is arranged laterally separate from the sensor region 108. In other examples, the sensor region 108 is partly or completely formed in the vertical direction z below the sensor pad 110. In the schematically illustrated example of FIG. 1, the sensor pad 110 is arranged laterally separately from the active cell region 104. That means, a region below the sensor pad 110 is devoid of active cells of the active cell region 104. In other examples, at least some of the active cells of the active cell region 104 are formed in the vertical direction z below the sensor pad 110.

As schematically illustrated in the cross-sectional view of FIG. 2, the active cell region 104 includes a plurality of active cell trenches 106_1 - 106_4 that are formed at the first main surface 102_1 of the semiconductor substrate 102 and that extend into the semiconductor substrate 102 along the vertical direction z. Neighboring active cell trenches 106_1 - 106_4 confine first mesa regions 130_1 – 130_3. Active cell electrodes 105_1 - 105_4 are formed in the active cell trenches 106_1 - 106_4 and the active cell electrodes 105_1 - 105_4 are separated from the semiconductor substrate 102 by a dielectric 107_1 - 107_4 that is arranged at a sidewall and at a bottom of the active cell trenches 106_1 - 106_. The active cell electrodes 105_1 - 105_4 may comprise a metal (e. g., Al, Cu, Ni, Pd, etc.), highly doped polysilicon, etc. The active cell region 104 further includes emitter regions 118 of a first conductivity type formed at the first main surface 102_1 of the semiconductor substrate 102 and body regions 112_1 of a second conductivity type that are formed between neighboring active cell trenches 106_1 - 106_4. The body regions 112_1 separate the emitter regions 118 from a drift region 124 of the first conductivity type that is arranged in the semiconductor substrate 102. The active cell region 104 further includes a collector region 120 of the second conductivity type formed at the second main surface 102_2 of the semiconductor substrate 102.

At least some of the plurality of active cell trenches 106_1 - 106_4 are gate trenches and gate electrodes are formed in the gate trenches. Within active cells, channels form in the body regions 112_1 along the gate trenches to provide an electrically conductive connection between the emitter regions 118 and the drift region 124. The channels are controlled by a voltage applied to the gate electrodes. The active cells located in the active cell region 104 are configured to conduct a load current between the first main surface 102_1 of the semiconductor substrate 102 and the second main surface 102_2 of the semiconductor substrate 102. The semiconductor device 100 may be referred to as vertical power semiconductor device and/or trench gate power semiconductor device. It may be configured to conduct load currents of more than 1 A or more than 10 A or more than 30 A or hundreds of A, like e. g., in automotive applications, and may be further configured to block voltages between load terminals in the range of tens up to several thousands of volts, e. g. 10V, 400 V, 650V, 1.2 kV, 1.7 kV, 3.3 kV, 4.5 kV, 5.5 kV, 6 kV, 6.5 kV, 10 kV.

A segmented first conductive layer is formed over the first main surface 102_1 of the semiconductor substrate 102. Segments of the first conductive layer may be electrically isolated from each other. A segment 122 of the first conductive layer provides an emitter potential to the emitter regions 118 and to the body region 112_1. The segmented first conductive layer is electrically isolated from the semiconductor substrate 102 and the active cell electrodes 105_1 - 105_4 by a segmented interlayer dielectric layer 126. The interlayer dielectric layer 126 is segmented by contact plugs that extend from the first conductive layer 122 through the interlayer dielectric layer 126 and through the emitter regions 118 into the body region 112_1 along the vertical direction z. The segment 122 of the first conductive layer may be referred to as first load terminal and/or emitter pad 122 of the semiconductor device 100 that is electrically connected to the emitter regions 118 and the body region 112_1 via the contact plugs.

A second conductive layer 128 is formed over the second main surface 102_2 of the semiconductor substrate 102 to provide a collector potential to the collector region 120. The second conductive layer 128 may be referred to as second load terminal and/or collector pad of the semiconductor device 100 that is electrically connected to the collector region 120. The first conductive layer 122 and/or the second conductive layer 128 may be a metallization layer.

In the example of FIG. 2, a contact plug is formed in each first mesa region between neighboring active cell trenches 106_1 - 106_4. In other examples, there may be first mesa regions between neighboring active cell trenches 106_1 - 106_4 that are devoid of contact plugs. In another example, the contact plugs extend through the interlayer dielectric layer 126 but not through the emitter regions 118. In this example, part of the body region 112_1 extends to the first main surface 102_1 of the semiconductor substrate 102 to form an electrical contact between the emitter pad 122, the emitter regions 118 and the body region 112_1 via the contact plugs.

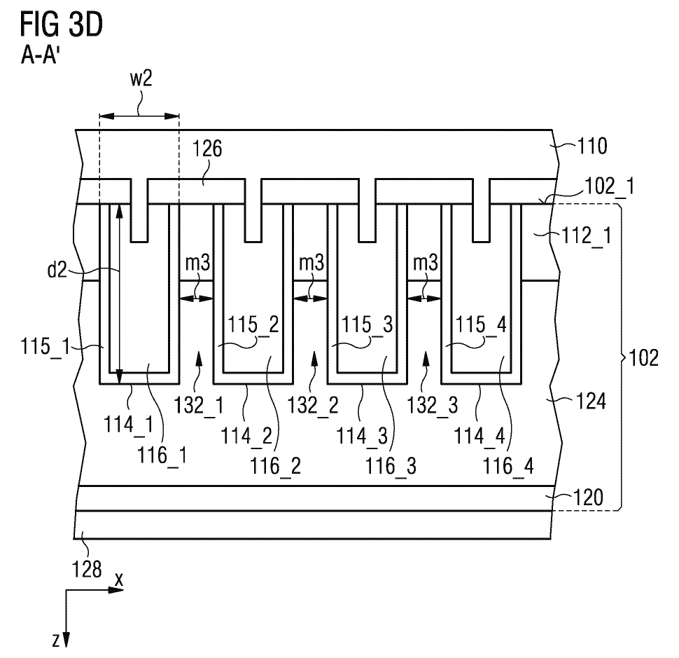

In one example, at least some of the active cell electrodes 105_1 - 105_4 formed in the plurality of active cell trenches 106_1 - 106_4 are electrically connected to an electrical potential other than a gate potential or are not electrically connected to a defined potential, i. e., they are configured to be electrically floating. As will be described in more detail in connection with FIG. 6A below, at least some of the active cell trenches 106_1 - 106_4 are emitter trenches and emitter electrodes formed in the emitter trenches are electrically connected to the emitter pad 122. In other examples, at least some of the plurality of active cell trenches 106_1 - 106_4 may include more than one electrode.

FIGS. 3A to 3D schematically illustrate cross-sectional views of implementations of the semiconductor device 100 along the line labelled A-A’ in FIG. 1. A semiconductor substrate region 112_1, 112_2 of the semiconductor substrate 102 is formed in the vertical direction z below the sensor pad 110. A plurality of capacitance trenches 114_1 - 114_4 are formed below the sensor pad 110 and extend from the first main surface 102_1 of the semiconductor substrate 102 into or through the semiconductor substrate region 112_1, 112_2 along the vertical direction z. Neighboring capacitance trenches 114_1 - 114_4 confine second mesa regions 132_1 – 132_3. In one example, the second mesa regions 132_1 – 132_3 are electrically isolated from the first mesa regions 130_1 – 130_3. Capacitance electrodes 116_1 – 116_4 are formed in the capacitance trenches 114_1 - 114_4 and the capacitance electrodes 116_1 – 116_4 are separated from the semiconductor substrate region 112_1, 112_2 by a dielectric 115_1 - 115_4 that is arranged at a sidewall and at a bottom of the capacitance trenches 114_1 - 114_4. The capacitance electrodes 116_1 – 116_4 may comprise a metal (e. g., Al, Cu, Ni, Pd, etc.), highly doped polysilicon, etc.

A drift region 124 separates the semiconductor substrate region 112_1, 112_2 from a collector region 120 that is formed at the second main surface 102_2 of the semiconductor substrate 102. The drift region 124 and the collector region 120 may be similar or identical to the drift region 124 and the collector region 120 as explained above. The sensor pad 110 is a segment 110 of a segmented first conductive layer that is formed over the first main surface 102_1 of the semiconductor substrate 102. The first conductive layer is electrically isolated from the semiconductor substrate 102 and the capacitance electrodes 116_1 – 116_4 by an interlayer dielectric layer 126. A second conductive layer 128 is formed over the second main surface 102_2 of the semiconductor substrate 102 to provide a collector potential to the collector region 120. The segmented first conductive layer, the interlayer dielectric layer 126 and the second conductive layer 128 may be similar or identical to the segmented first conductive layer, the interlayer dielectric layer 126 and the second conductive layer 128 as explained above in connection with FIG. 2. The sensor pad 110 may be electrically isolated from the emitter pad 122 of FIG. 2.

An input capacitance of semiconductor device 100 is formed below the sensor pad 110 and the capacitance trenches 114_1 - 114_4 are part of this input capacitance. The input capacitance may be referred to as (input) trench capacitance. A first electrode of the input capacitance is formed by one of the capacitance electrodes 116_1 – 116_4 or by the semiconductor substrate region 112_1, 112_2. The first electrode of the input capacitance may be referred to as first terminal or first conductor of the input capacitance.

In the example of FIG. 3A, the sensor pad 110 is electrically connected to the capacitance electrodes 116_1 – 116_4 to form the first electrode of the input capacitance. The capacitance electrodes 116_1 – 116_4 extend through a semiconductor substrate region 112_1 into the drift region 124. The semiconductor substrate region 112_1 may be similar or identical to the body regions 112_1 of the active cell region 104. The semiconductor substrate region 112_1 may be electrically coupled to the body regions 112_1 of the active cell region 104 that are at emitter potential. The semiconductor substrate region 112_1 may be referred to as body region 112_1. The first electrode of the input capacitance is capacitively coupled to the semiconductor substrate region 112_1 and the semiconductor substrate region 112_1 forms a second electrode of the input capacitance. The input capacitance may be referred to as sensor pad-emitter capacitance or first input capacitance C1.

A further input capacitance may be formed below the sensor pad 110. The further input capacitance may be referred to as second input capacitance C2. A first electrode of the second input capacitance C2 is formed by the capacitance electrodes 116_1 – 116_4 that are electrically connected to the sensor pad 110. The capacitance electrodes 116_1 – 116_4 are capacitively coupled to the collector region 120 that is at collector potential. The collector region 120 forms a second electrode of the second input capacitance C2. The second input capacitance C2 may be referred to as sensor pad-collector capacitance.

In the example of FIG. 3A, each capacitance electrodes 116_1 – 116_4 is electrically connected to the sensor pad 110. In other examples, at least some of the capacitance electrodes 116_1 – 116_4 may be electrically connected differently. In one example, some of the capacitance electrodes 116_1 – 116_4 may be electrically connected to the gate electrodes of the active cell region 104 that are at the gate potential. In this example, a further input capacitance may be formed below the sensor pad 110. The further input capacitance may be referred to as third input capacitance C3. A first electrode of the third input capacitance C3 is formed by capacitance electrodes 116_1 – 116_4 that are electrically connected to the sensor pad 110. A second electrode of the third input capacitance C3 is formed by capacitance electrodes 116_1 – 116_4 at the gate potential. In this example, the first electrode at sensor pad potential is capacitively coupled to the second electrode at the gate potential and the third input capacitance C3 may be referred to as sensor pad-gate capacitance. In another example, a further capacitance electrode of the capacitance electrodes 116_1 – 116_4 may be electrically connected to the emitter pad 122 and forms a first electrode of a further input capacitance.

The sensor device may be susceptible to damage caused by an ESD event due to its small size and the associated low capacitance. The additional input capacitance(s) that is/are formed below the sensor pad 110 extend(s) the charge storage capability of the semiconductor device 100 including the sensor device. As a result, the semiconductor device 100 including the sensor device is protected from damage in case of an ESD event received by the semiconductor device 100 via one of its pads, e. g., received via the sensor pad 110. The additional input capacitance(s) and the sensor device are monolithically integrated in the semiconductor device 100 and the overall ESD ruggedness of the semiconductor device 100 is enhanced. This enhancement happens in an area-optimized and cost-effective way as a region under the sensor pad that may not be used for other purposes can be used. The processing of the additional input capacitance(s) may be done based on existing process steps without any modifications or additions to the production flow of the overall chip.

FIG. 3B schematically illustrates a cross-sectional view of a further implementation of the semiconductor device 100 along the line labelled A-A’ in FIG. 1. The implementation of FIG. 3B is similar to the implementation of FIG. 3A. Differently, however, in FIG. 3B the sensor pad 110 is electrically connected to the semiconductor substrate region 112_1 via contact plugs. The semiconductor substrate region 112_1 below the sensor pad 110 is at a different electrical potential than the body regions 112_1 of the active cell region 104. Therefore, the semiconductor substrate region 112_1 below the sensor pad 110 must be electrically isolated from the body regions 112_1 of the active cell region 104. That means, the second mesa regions 132_1 – 132_3 are electrically isolated from the first mesa regions 130_1 – 130_3. The semiconductor substrate region 112_1 below the sensor pad 110 forms a first electrode of a first input capacitance. A second electrode of the first input capacitance may be formed by the collector region 120 and/or by at least one of the capacitance electrodes 116_1 – 116_4. In one example, the capacitance electrodes 116_1 – 116_4 may all be electrically connected to a same electrical potential. In another example, the capacitance electrodes 116_1 – 116_4 may be connected to different electrical potentials to form further input capacitances.

In the example of FIG. 3B, a contact plug is formed in each second mesa region of the semiconductor substrate region 112_1 between neighboring capacitance trenches 114_1 - 114_4. In other examples, there may be second mesa regions of the semiconductor substrate region 112_1 between neighboring capacitance trenches 114_1 - 114_4 that are devoid of contact plugs. In the example of FIG. 3B, the semiconductor substrate region 112_1 below the sensor pad 110 is at the sensor pad potential. In the example of FIG. 3A, the semiconductor substrate region 112_1 below the sensor pad 110 is at the emitter potential. In another examples, the semiconductor substrate region 112_1 below the sensor pad 110 is not electrically connected to a defined potential, i. e., it is configured to be electrically floating.

FIG. 3C schematically illustrates a cross-sectional view of a further implementation of the semiconductor device 100 along the line labelled A-A’ in FIG. 1. The implementation of FIG. 3C is similar to the implementation of FIG. 3B. Differently, however, the semiconductor substrate region 112_2 of FIG. 3C extends from first main surface 102_1 of the semiconductor substrate 102 deeper into the semiconductor substrate 102 along the vertical direction z than the semiconductor substrate 112_1 of FIG. 3B. The semiconductor substrate region 112_2 of FIG. 3C may be referred to as well region 112_2 or deep well region 112_2. The well region 112_2 may be similar or identical to well regions formed in other parts of the semiconductor device 100. For example, a well region similar or identical to the well region 112_2 may be formed in an edge termination region of the semiconductor device 100. The plurality of capacitance trenches 114_1 - 114_4 extend into the well region 112_2 but do not extend through the well region 112_2. That means, the plurality of capacitance trenches 114_1 - 114_4 do not penetrate the well region 112_2 and bottoms of the plurality of capacitance trenches 114_1 - 114_4 reside within the well region 112_2.

In the example of FIG. 3C, the sensor pad 110 is electrically connected to the well region 112_2 via contact plugs and the well region 112_2 forms an electrode of an input capacitance. In other examples, the well region 112_2 may be electrically connected to a different electrical potential to form the electrode of the input capacitance. For example, the well region 112_2 may be electrically connected to the emitter potential of the active cell region 104 similar to semiconductor substrate region 112_1 as described above in connection with FIG. 3A. In another examples, the well region 112_2 is not electrically connected to a defined potential, i. e., it is configured to be electrically floating.

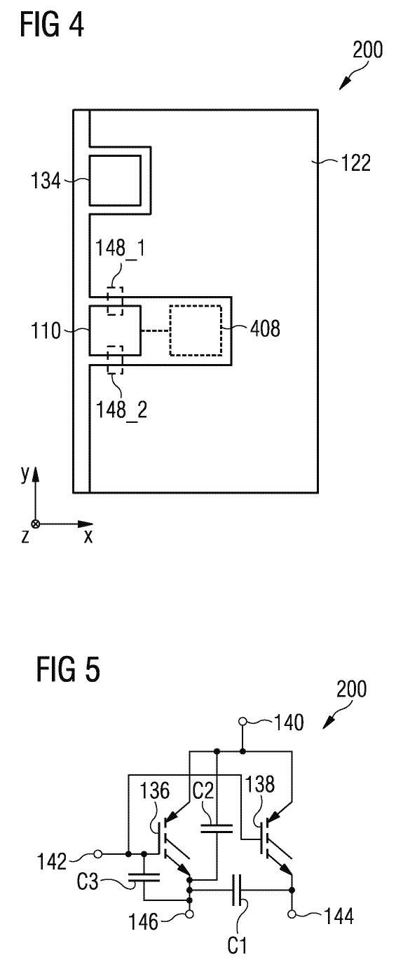

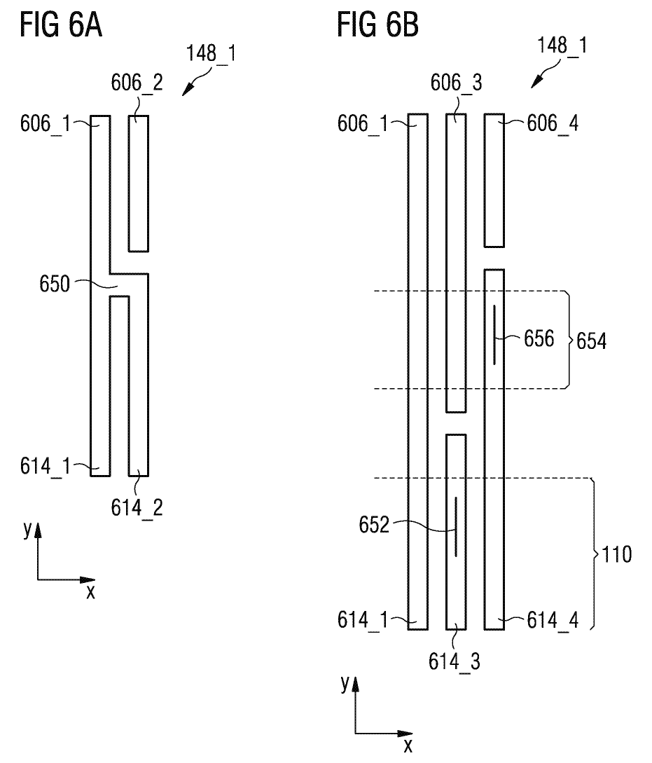

In one example, the implementations of FIG. 3B and FIG. 3C may be combined and a first part of the semiconductor substrate region below the sensor pad 110 may be a body region 112_1 and a second part of the semiconductor substrate region below the sensor pad may be a well region 112_2. The body region 112_1 may be electrically isolated from the well region 112_2 as will be described in more detail in connection with FIG. 7A and FIG. 7B below.

As illustrated in FIG. 2, the active cell trenches 106_1 - 106_4 of the active cell region 104 extend from the first main surface 102_1 of the semiconductor substrate 102 to a first depth d1 within the semiconductor substrate 102. Further, the active cell trenches 106_1 - 106_4 have a first width w1. As illustrated in FIGS. 3A – 3D, the capacitance trenches 114_1 - 114_4 below the sensor pad 110 extend from the first main surface 102_1 of the semiconductor substrate 102 to a second depth d2 within the semiconductor substrate 102. Further, the capacitance trenches 114_1 - 114_4 have a second width w2. In one example, the active cell trenches 106_1 - 106_4 have at least one of the same width w1, w2 or the same depth d1, d2 as the capacitance trenches 114_1 - 114_4. Such a regular structure allows for an eased manufacturing of the semiconductor device 100. In other examples, the first width w1 is different from the second width w2 and/or the first depth d1 is different from the second depth d2. The active cells and the additional input capacitance(s) may be manufactured using common processing steps and no additional manufacturing steps may be required to manufacture the additional input capacitance(s). That means, the semiconductor device including the additional input capacitance(s) can be manufactured in a cost-efficient manner.

As illustrated in the examples of FIG. 2 and FIGS. 3A-3C, the first mesa regions 130_1 – 130_3 of the active cell region 104 have a first width m1 and the second mesa regions 132_1 – 132_3 below the sensor pad 110 have a second width m2. The first width m1 is similar or same as the second width m2. Differently, in the example of FIG. 3D, the second mesa regions 132_1 – 132_3 below sensor pad 110 have a third width m3 that is less than the first width m1. A smaller width m3 of second mesa regions 132_1 – 132_3 below the sensor pad 110 allows for an increased density of the input capacitance(s) that is/are formed below the sensor pad 110. In the example of FIG. 3D, a body region 112_1 similar or identical to the body region 112_1 of FIG. 3A is formed below the sensor pad 110. In another example, a well region 112_2 similar or identical to the well region 112_2 of FIG. 3C is formed below the sensor pad 110. Due to their smaller widthm3, the second mesa regions 132_1 – 132_3 may be devoid of contact plugs.

As illustrated in the top view of FIG. 1, the plurality of capacitance trenches 114_1 - 114_4 as illustrated and described in connection with FIGS. 3A to 3D above may be limited to an area below the sensor pad 110. In other examples (not illustrated), the plurality of capacitance trenches 114_1 -114_4 may extend to an area outside the sensor pad 110. The plurality of capacitance trenches 114_1 - 114_4 are formed separately from the sensor device. The plurality of capacitance trenches 114_1 - 114_4 and the sensor device are distinct functional units.

FIG. 4 schematically illustrates a partial top view of a further exemplary semiconductor device 200. The semiconductor device 200 includes a sensor pad 110 that is similar or same as the sensor pad 110 of FIG. 1. The semiconductor device 200 further includes an emitter pad 122 that is similar or same as the emitter pad 122 of FIG. 2. An active cell region (not illustrated) similar or same as the active cell region 104 described in connection with FIG. 2 above is formed at least partly below the emitter pad 122. The semiconductor device 200 further includes a gate pad 134. The gate pad 134 may be formed in a same conductive layer as the sensor pad 110 and the emitter pad 122. The gate pad 134 is electrically connected to gate electrodes formed in at least some of the plurality of active cell trenches 106_1 - 106_4 of the active cell region 104 as described in connection with FIG. 2 above. The semiconductor device 200 further includes a collector pad similar or same as the collector pad described in connection with FIG. 2. The collector pad is formed at a second main surface of a semiconductor substrate of the semiconductor device 200 and is therefore out of view in FIG. 4. The semiconductor device 200 further includes a sensor region 408 indicated by dotted lines that is similar or same as the sensor region 108 described in connection with FIG. 1 above. A first terminal of a sensor device in the sensor region 408 is electrically connected to the sensor pad 110 as indicated by dotted lines in FIG. 4.

In the example of FIG. 4, the sensor device of the sensor region 408 is a current sensor device that is configured to allow for a measurement of a current in the sensor region 408. The sensor region 408 includes a plurality of current sensor cells that are electrically coupled in parallel to form a current sensor transistor. The current sensor cells of the current sensor transistor mirror a current flowing in the active cell region 104 and a current flowing through the current sensor cells can be used to sense the current flowing through the plurality of active cells of the active cell region 104. That means, a current that is measured in the current sensor cells represents a current that flows through the active cells of active cell region 104. The active cells and the current sensor cells may have a same configuration, pitch, etc., but with fewer current sensor cells than active cells, e.g., 1/10, 1/100, 1/1000 or even fewer cells as compared to the active cells. A current flowing through the active cells may be determined based on the current flowing through the current sensor cells and a ratio of a size of the active cells to a size of the current sensor cells.

The current sensor device includes emitter regions of the first conductivity type formed at the first main surface 102_1 of the semiconductor substrate 102 similar or same as the emitter regions 118 of the active cell region 104 as illustrated and described in connection with FIG. 2 above. The current sensor device further includes a plurality of current sensor cell trenches extending from the first main surface 102_1 of the semiconductor substrate 102 into the semiconductor substrate 102 similar or same as the plurality of active cell trenches 106_1 - 106_4 as illustrated and described in connection with FIG. 2 above. Gate electrodes are formed in at least some of the plurality of current sensor cell trenches. The current sensor device further includes a collector region formed at the second main surface of the semiconductor substrate 102 similar or same as the collector region 120 of the active cell region 104 as illustrated and described in connection with FIG. 2 above.

FIG. 5 illustrates a circuit schematic of an implementation of a current sensor transistor 136 formed by the plurality of current sensor cells of the sensor region 408 as described in connection with FIG. 4 above and a main transistor 138 formed by the plurality of active cells of the active cell region 104 as described in connection with FIG. 4 above. The collector region of the main transistor 138 and the collector region of the current sensor transistor 136 are both electrically connected to a collector terminal 140 of the semiconductor device 200. The collector terminal 140 is electrically connected to the collector pad as described in connection with FIG. 4 above. The gate electrodes formed in at least some of the active cell trenches of the main transistor 138 and the gate electrodes formed in at least some of the current sensor cell trenches of the current sensor transistor 136 are all electrically connected to a gate terminal 142 of the semiconductor device 200. The gate terminal 142 is electrically connected to the gate pad 134 as illustrated and described in connection with FIG. 4 above. The emitter regions of the main transistor 138 are electrically connected to an emitter terminal 144 of the semiconductor device 200. The emitter terminal 144 is electrically connected to the emitter pad 122 as illustrated and described in connection with FIG. 4 above. The emitter regions of the current sensor transistor 136 are electrically connected to a current sensor terminal 146 of the semiconductor device 200. The current sensor terminal 146 corresponds to the first terminal of a sensor device in the sensor region 408 that is electrically connected to the sensor pad 110 as described in connection with FIG. 4 and as indicated by dotted lines in FIG. 4.

As described in connection with FIG. 3A above, due to the small size of the sensor region 408, the current sensor transistor 136 has a low associated input capacitance. Consequently, the current sensor transistor 136 may be weak in terms of ESD ruggedness. To improve the ESD ruggedness, (an) additional input capacitance(s) is/are formed below the sensor pad 110. A first input capacitance C1 may be formed below the sensor pad 110 similar or same as the first input capacitance C1 as illustrated and described in connection with FIGS. 3A-3D above. The first input capacitance C1 may be referred to as sensor pad-emitter capacitance. Alternatively or additionally, a second input capacitance C2 may be formed below the sensor pad 110 similar or same as the second input capacitance C2 as illustrated and described in connection with FIGS. 3A-3D above. The second input capacitance C2 may be referred to as sensor pad-collector capacitance. Alternatively or additionally, a third input capacitance C3 may be formed below the sensor pad 110 similar or same as the third input capacitance C3 as illustrated and described in connection with FIGS. 3A-3D above. The third input capacitance C3 may be referred to as sensor pad-gate capacitance. Besides the improvement in terms of ESD robustness, the additional input capacitance(s) may reduce or prevent the formation of oscillations between the active cell region 104 and the sensor region 408 that may arise under a short circuit condition. The additional input capacitance(s) may shift resonance conditions to an area outside of any operation conditions of the semiconductor device 200.

As illustrated by dashed lines in FIG. 4, transition regions 148_1, 148_2 are arranged at an interface between the region below the sensor pad 110 and the active cell region 104 that is at least formed partly below the emitter pad 122. FIGS. 6A and 6B schematically illustrate partial top views of the transition region 148_1. The transition region 148_2 may be similar or same as the transition region 148_1. The active cell region 104 comprises a plurality of stripe-shaped active cell trenches 606_1 – 606_4 that extend in parallel along the first lateral direction y. Besides, a plurality of stripe-shaped capacitance trenches 614_1 – 614_4 that extend in parallel along the first lateral direction y are formed below the sensor pad 110.

In the example of FIG. 6A, a first capacitance trench 614_1 extends uninterrupted into the active cell region 104. The first capacitance trench 614_1 merges into a first active cell trench 606_1 and the first capacitance trench 614_1 and the first active cell trench 606_1 form a contiguous and straight trench structure. The first capacitance trench 614_1 and the first active cell trench 606_1 may be referred to as uninterrupted trenches. The implementation of uninterrupted trenches 606_1, 614_1 allows to provide an electrical potential from the active cell region 104 to the region below the sensor pad 110. For example, the first active cell trench 606_1 is an emitter trench 606_1 and an active cell electrode formed in the emitter trench 606_1 is electrically connected to the emitter pad 122. The electrical potential of the emitter pad 122 is provided to the region below the sensor pad 110 via the uninterrupted trenches 606_1, 614_1.

As illustrated in FIG. 6A, a second active cell trench 606_2 does not extend into the region below the sensor pad 110. Similarly, a second capacitance trench 614_2 does not extend into the active cell region 104. The second active cell trench 606_2 and/or the second capacitance trench 614_2 may be referred to as interrupted trenches 606_2, 614_2. The implementation of interrupted trenches 606_2, 614_2 allows for an electrical connection of capacitance electrodes formed in the capacitance trenches 614_1 – 614_4 independent from an electrical connection of active cell electrodes formed in the active cell trenches 606_1 – 606_4. The second capacitance trench 614_2 is connected to the first capacitance trench 614_1 via a trench segment 650 that extends in a second lateral direction x. The second lateral direction x is transverse to the first lateral direction y. The trench segment 650 may be referred to as intersecting trench 650. An electrical potential is provided from the first capacitance trench 614_1 to the neighboring second capacitance trench 614_2 via an electrode formed in the intersecting trench 650.

FIG. 6B schematically illustrates a partial top view of a further implementation of the transition region 148_1. Similar to the implementation of FIG. 6A, the first capacitance trench 614_1 and the first active cell trench 606_1 are uninterrupted trenches. Besides, there are interrupted capacitance trenches 614_3, 614_4 and interrupted active cell trenches 606_3, 606_4. Differently, however, in FIG. 6B the interrupted capacitance trenches 614_3, 614_4 are not connected to each other via an intersecting trench. In the example of FIG. 6B, a capacitance electrode formed in a first interrupted capacitance trenches 614_3 is electrically connected to the sensor pad 110 via an electrical connection 652. That means, the capacitance electrode formed in a first interrupted capacitance trench 614_3 is at the sensor pad potential. The electrical connection 652 may be similar or same as the contact plugs illustrated and described in connection with FIG. 3A. Further, a capacitance electrode formed in a second interrupted capacitance trenches 614_4 is electrically connected to a conductive line 654 via an electrical connection 656. The electrical connection 656 may be similar or same as the contact plugs illustrated and described in connection with FIG. 3A above. The conductive line 654 may be a segment of the segmented first conductive layer as described in connection with FIG. 2 and FIGS. 3A to 3D above. The conductive line 654 and therefore also the capacitance electrode formed in the second interrupted capacitance trenches 614_4 may be at the gate potential.

In one example, the implementations of FIG. 6A and FIG. 6B may be combined. The transition region 148_1 as illustrated and described in connection with FIG. 6B may include further interrupted active cell trenches and/or further interrupted capacitance trenches that are connected to each other via an intersecting trench. This intersecting trench may be similar or same as the intersecting trench 650 as illustrated and described in connection with FIG. 6A. The implementation of uninterrupted trenches 606_1, 614_1, interrupted trenches 606_2 - 606_4, 614_2 - 614_4 and/or intersecting trench 650 as illustrated and described in connection with FIG. 6A and 6B above allows for a flexible assignment of capacitance electrodes formed in the capacitance trenches 614_1 - 614_4 to different electrical potentials depending on which capacitive effect needs to be enhanced.

FIG. 7A schematically illustrates a top view of an implementation of the semiconductor substrate region 112_1, 112_2 below the sensor pad 110. The semiconductor substrate region 112_1, 112_2 below the sensor pad 110 includes a first part 758 and a second part 760. FIG. 7B schematically illustrates an enlarged top view of an implementation of an interface region between the first part 758 and the second part 760. In the first part 758, the semiconductor substrate region 112_1, 112_2 below the sensor pad 110 may be at a different electrical potential than in the second part 760 of semiconductor substrate region 112_1, 112_b below the sensor pad 110. The first part 758 below the sensor pad 110 may be a body region 112_1 similar or same as the body region 112_1 illustrated and described in connection with FIG. 3A and FIG. 3B above. The body region of the first part 758 is electrically connected to the sensor pad 110 that is formed over the first part 758 and the second part 760. The body region of the first part 758 is electrically connected to the sensor pad 110 via electrical connections 762 that may be similar or same as the contact plugs illustrated and described in connection with FIG. 3A above. The second part 760 below the sensor pad may be a well region similar or same as the well region 112_2 illustrated and described in connection with FIG. 3C above. The well region of the second part 760 is electrically connected to a different electrical potential than the body region of the first part 758. For example, the well region of the second part 760 is electrically connected to the emitter potential.

As illustrated in FIG. 7B, the body region of the first part 758 is electrically isolated from the well region of the second part 760 by an isolation trench 764_1, 764_2. A first segment 764_1 of the isolation trench extends in parallel to a plurality of stripe-shaped capacitance trenches of the first part 758 and the second part 760. A second segment 764_2 of the isolation trench extends transverse to the first segment 764_1 in an interface region between the first part 758 and the second part 760. The second segment 764_2 intersects the first segment 764_1. In one example, an isolation electrode formed in the isolation trench 764_1, 764_2 may be at the gate potential. In other examples, the isolation electrode formed in the isolation trench 764_1, 764_2 may be at a different potential or may be configured to be electrically floating.

As further illustrated in FIG. 7B, at least some of the stripe-shaped capacitance trenches of the first part 758 and of the second part 760 merge into the isolation trench 764_1, 764 to form a contiguous trench structure containing a common electrode at gate potential. Electrodes formed in at least some other of the stripe-shaped capacitance trenches of the first part 758 and of the second part 760 may be electrically connected to different electrical potentials as described in connection with FIG. 3A above. In the example of FIG. 7B, the first part 758 is completely surrounded by the second part 760. In other examples, the first part 758 is arranged at a side or at a corner of the second part 760. That means, the first part 758 is just partly surrounded by the second part 760.

FIG. 8 schematically illustrates a partial top view of a further exemplary semiconductor device 300. Similar to the implementation of FIG. 4, the semiconductor device 300 includes a sensor pad 110, an emitter pad 122, a gate pad 134 and a sensor region 808 indicated by dotted lines. An active cell region (not illustrated) is formed at least partly below the emitter pad 122. A collector pad is formed at a second main surface of a semiconductor substrate of the semiconductor device 300 and is therefore out of view in FIG. 8. A first terminal of a sensor device in the sensor region 808 is electrically connected to the sensor pad 110 as indicated by dotted lines in FIG. 8. In contrast to the example of FIG. 4, the sensor device in the sensor region 808 of the example of FIG. 8 further includes a second terminal that is electrically connected to a further sensor pad 866 as indicated by dotted lines. In the example of FIG. 8, the sensor device of the sensor region 808 is a temperature sensor device that is configured to allow for a measurement of a temperature of the semiconductor device 300.

FIG. 9 illustrates a circuit schematic of an implementation of a temperature sensor device 968 and a main transistor 138 formed by the plurality of active cells of the active cell region. A collector region of the main transistor 138 is electrically connected to a collector terminal 140 of the semiconductor device 300. The collector terminal 140 is electrically connected to the collector pad as described in connection with FIG. 8 above. Gate electrodes formed in at least some of the active cell trenches of the main transistor 138 are electrically connected to a gate terminal 142 of the semiconductor device 300. The gate terminal 142 is electrically connected to the gate pad 134 as illustrated and described in connection with FIG. 8 above. Emitter regions of the main transistor 138 are electrically connected to an emitter terminal 144 of the semiconductor device 300. The emitter terminal 144 is electrically connected to the emitter pad 122 as illustrated and described in connection with FIG. 8 above. A first terminal 970 of the temperature sensor device 968 is electrically connected to the sensor pad 110 illustrated and described in connection with FIG. 8 above. A second terminal 972 of the temperature sensor device 968 is electrically connected to the further sensor pad 866 illustrated and described in connection with FIG. 8 above.

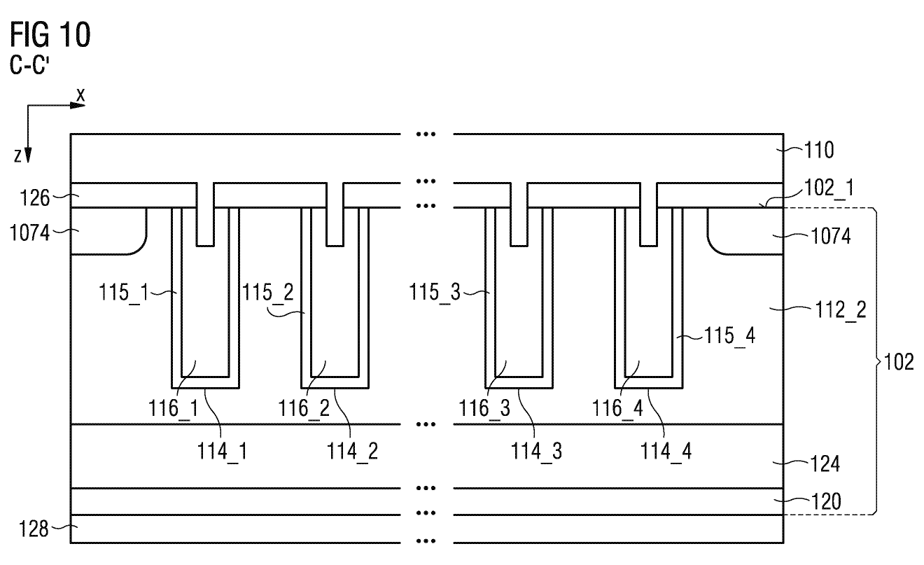

In the example of FIG. 9, the temperature sensor device 968 includes a plurality of diodes coupled in series and an antiparallel diode coupled between the first terminal 970 and the second terminal 972. For example, the diodes are polysilicon diodes. In other examples, the temperature sensor device may contain less, additional or different elements. In one example, the antiparallel diode may be omitted. In another example, the antiparallel diode may be replaced by an equivalent plurality of diodes in series oriented in opposite polarity with respect to the first series, so that the temperature can be read also when opposite polarity is applied. In yet another example, the temperature sensor device 968 includes a resistor. The temperature sensor device 968 is electrically isolated from the main transistor 138 by an isolation structure. The isolation structure may include an interlayer dielectric layer similar or identical to the interlayer dielectric layer 126 as explained above. Additionally or alternatively, the isolation structure may include an oxide region, for example a LOCOS (Local Oxidation of Silicon) region as will be described in more detail in connection with FIG. 10 below. The temperature sensor device 968 may be referred to as isolated temperature sensor device 968. The temperature sensor device 968 may be protected by a well region that is formed below the temperature sensor device 968 and that is electrically connected to the emitter potential of the main transistor 138. In one example, the well region is a deep p-doping diffusion that is formed below the temperature sensor device 968, the sensor pad 110, the further sensor pad 866 and the electrical connection between the temperature sensor device 968 and the sensor pad 110/further sensor pad 866.

The isolation structure may provide an insufficient isolation of the temperature sensor device 968 in case of an ESD event received by the semiconductor device 300 via one of its pads. To increase the charge storage capability of the semiconductor device 300, (an) additional input capacitance(s) is/are formed below the sensor pad 110 as will be described in more detail in connection with FIG. 10 below. Besides (an) additional input capacitance(s) is/are formed below the further sensor pad 866. The increased charge storage capability extends the ability of the semiconductor device 300 to incorporate charge in case of an ESD event. The generation of voltage levels which could break the isolation structure may be reduced or prevented and therefore, the temperature sensor device 968 is protected from damage in case of an ESD event. The ESD ruggedness of the semiconductor device 300 is improved. The additional input capacitances are implemented in an area-efficient way as an area below the sensor pads 110, 866 is used that may not be used for any other purpose.

FIG. 10 schematically illustrates a cross-sectional view of an implementation of the semiconductor device 300 along the line labelled C-C’ in FIG. 8. A similar or identical implementation may be included below the further sensor pad 866. The implementation of FIG. 10 is similar or identical to one of the implementations as illustrated and described in connection with FIGS. 3A to 3D above. A plurality of capacitance trenches 114_1 - 114_4 are formed below the sensor pad 110 and extend from the first main surface 102_1 of the semiconductor substrate 102 into the semiconductor substrate region 112_2 along the vertical direction z. Capacitance electrodes 116_1 – 116_4 are formed in the capacitance trenches 114_1 - 114_4 and the capacitance electrodes 116_1 – 116_4 are separated from the semiconductor substrate region 112_1, 112_2 by a dielectric 115_1 - 115_4 that is arranged at a sidewall and at a bottom of the capacitance trenches 114_1 - 114_4. A drift region 124 separates the semiconductor substrate region 112_2 from a collector region 120 that is formed at the second main surface 102_2 of the semiconductor substrate 102. The sensor pad 110 is a segment 110 of a segmented first conductive layer that is formed over the first main surface 102_1 of the semiconductor substrate 102. The first conductive layer is electrically isolated from the semiconductor substrate 102 by an interlayer dielectric layer 126. A second conductive layer 128 is formed over the second main surface 102_2 of the semiconductor substrate 102 to provide a collector potential to the collector region 120.

In the example of FIG. 10, an isolation structure 1074, e. g., a LOCOS (Local Oxidation of Silicon) region 1074, is formed at the first main surface 102_1 of the semiconductor substrate region 102 to provide for an electrical isolation. The interlayer dielectric layer 126 and/or the LOCOS (Local Oxidation of Silicon) region 1074 may also be included in the temperature sensor device 986 to provide for an electrical isolation. In the example of FIG. 10, the semiconductor substrate region 112_2 is a well region 112_2 or deep well region 112_2 similar or identical to the semiconductor substrate region 112_2 as illustrated and described in connection with FIG. 3C above. The (deep) well region 112_2 is electrically coupled to the emitter potential of the main transistor 138. The (deep) well region 112_2 may also be included in the temperature sensor device 986 to protection the temperature sensor device 986.

In the example of FIG. 10, the sensor pad 110 is electrically connected to the capacitance electrodes 116_1 – 116_4 to form a first electrode of a fourth input capacitance C4. The (deep) well region 112_2 forms a second electrode of the fourth input capacitance C4. In addition, a fifth input capacitance C5 may be formed below the sensor pad 110. A first electrode of the fifth input capacitance C5 is formed by the capacitance electrodes 116_1 – 116_4 that are electrically connected to the sensor pad 110. The collector region 120 forms a second electrode of the fifth input capacitance C5. A sixth input capacitance C6 similar or same as the fourth input capacitance C4 may be formed below the further sensor pad 866. Besides, a seventh input capacitance C7 similar or same as the fifth input capacitance C5 may be formed below the further sensor pad 866.

Implementation examples as illustrated and described in connection with the current sensor device may be combined with/integrated in implementation examples as illustrated and described in connection with the temperature sensor device and vice versa. In one example, a transition region similar or same as the transition regions 148_1, 148_2 of FIG. 6A and FIG. 6B may be included in the semiconductor device 300 that includes the temperature sensor device. In another example, both a temperature sensor device as illustrated and described above, and a current sensor device as illustrated and described above may be monolithically integrated on a same semiconductor device.

Examples of the present invention are summarized here. Other examples can also be understood from the entirety of the specification and the claims filed herein.

Example 1: A semiconductor device, comprising a semiconductor substrate, an active cell region comprising a plurality of active cell trenches extending from a first main surface of the semiconductor substrate into the semiconductor substrate; a sensor region comprising a sensor device; a sensor pad formed over the first main surface of the semiconductor substrate and electrically connected to a first terminal of the sensor device; a semiconductor substrate region of the semiconductor substrate formed below the sensor pad; and a plurality of capacitance trenches formed below the sensor pad and extending from the first main surface of the semiconductor substrate into or through the semiconductor substrate region, wherein one of a capacitance electrode formed in one of the plurality of capacitance trenches or the semiconductor substrate region is electrically connected to the sensor pad and forms a first electrode of an input capacitance.

Example 2: The semiconductor device of example 1, wherein the other one of the capacitance electrode formed in one of the plurality of capacitance trenches or the semiconductor substrate region forms a second electrode of the input capacitance.

Example 3: The semiconductor device of any of the preceding examples, wherein the plurality of active cell trenches have at least one of a same width or a same depth as the plurality of capacitance trenches.

Example 4: The semiconductor device of any of the preceding examples, wherein the active cell region comprises a plurality of active cells, and wherein a region below the sensor pad is devoid of active cells.

Example 5: The semiconductor device of any of the preceding examples, wherein the active cell region comprises: a source/emitter region formed at the first main surface of the semiconductor substrate; and a drain/collector region formed at a second main surface of the semiconductor substrate opposite the first main surface, and wherein the semiconductor device further comprises: a source/emitter pad formed over the first main surface of the semiconductor substrate and electrically connected to the source/emitter region; and a gate pad formed over the first main surface of the semiconductor substrate and electrically connected to gate electrodes formed in at least some of the plurality of active cell trenches of the active cell region.

Example 6: The semiconductor device of any of the preceding examples, wherein the sensor region comprises a temperature sensor device configured to allow for a measurement of a temperature of the semiconductor device.

Example 7: The semiconductor device of example 6, wherein the temperature sensor device comprises at least one of a resistor or a plurality of diodes coupled in series.

Example 8: The semiconductor device of any of examples 6 or 7, further comprising: a further sensor pad formed over the first main surface of the semiconductor substrate and electrically connected to a second terminal of the temperature sensor device; a further semiconductor substrate region of the semiconductor substrate formed below the further sensor pad; and a plurality of further capacitance trenches formed below the further sensor pad and extending from the first main surface of the semiconductor substrate into or through the further semiconductor substrate region, wherein at least one of a capacitance electrode formed in one of the plurality of further capacitance trenches or the further semiconductor substrate region is electrically connected to the further sensor pad and forms a first electrode of a further input capacitance.

Example 9: The semiconductor device of any of examples 1 to 5, wherein the sensor region comprises a current sensor device configured to allow for a measurement of a current in the sensor region.

Example 10: The semiconductor device of example 9, wherein the current sensor device comprises source/emitter regions formed at the first main surface of the semiconductor substrate and electrically connected to the sensor pad.

Example 11: The semiconductor device of any of examples 9 or 10 in combination with example 5, wherein the current sensor device comprises: a plurality of current sensor cell trenches extending from the first main surface of the semiconductor substrate into the semiconductor substrate, wherein gate electrodes formed in at least some of the plurality of current sensor cell trenches of the current sensor device are electrically connected to the gate pad; and a drain/collector region formed at the second main surface of the semiconductor substrate and electrically connected to the drain/collector region of the active cell region.

Example 12: The semiconductor device of any of examples 9 to 11 in combination with example 5, further comprising: a plurality of capacitance electrodes formed in the plurality of capacitance trenches, wherein at least one of the plurality of capacitance electrodes is electrically connected to one of the sensor pad, the gate pad or the source/emitter pad and forms the first electrode of the input capacitance.

Example 13: The semiconductor device of example 12, wherein a second capacitance electrode of the plurality of capacitance electrodes is electrically connected to another one of the sensor pad, the gate pad or the source/emitter pad and forms a first electrode of a second input capacitance.

Example 14: The semiconductor device of any of examples 9 to 13 in combination with example 5, further comprising: a plurality of capacitance electrodes formed in the plurality of capacitance trenches, wherein a first capacitance electrode of the plurality of capacitance electrodes is electrically connected to the sensor pad and forms the first electrode of the input capacitance, wherein a further capacitance electrode of the plurality of capacitance electrodes is electrically connected to the source/emitter pad and forms a first electrode of a further input capacitance, and wherein a third capacitance electrode of the plurality of capacitance electrodes is electrically connected to the gate pad and forms a first electrode of a third input capacitance.

Example 15: The semiconductor device of any of the preceding examples, wherein the plurality of capacitance trenches extend in parallel along the first main surface of the semiconductor substrate, and wherein at least one of the plurality of capacitance trenches extends uninterrupted into the active cell region.

Example 16: The semiconductor device of any of the preceding examples, wherein the plurality of capacitance trenches extend in parallel along the first main surface of the semiconductor substrate, and wherein neighboring capacitance trenches are connected to each other via an intersecting trench that extends transverse to the plurality of capacitance trenches.

Example 17: The semiconductor device of any of the preceding examples, wherein the semiconductor substrate region is electrically connected to the sensor pad.

Example 18: The semiconductor device of any of examples 1 to 16, wherein the active cell region comprises: a source/emitter region formed at the first main surface of the semiconductor substrate, wherein the semiconductor device further comprises: a source/emitter pad formed over the first main surface of the semiconductor substrate and electrically connected to the source/emitter region, wherein the semiconductor substrate region is electrically connected to the source/emitter pad.

Example 19: The semiconductor device of any of the preceding examples, wherein neighboring active cell trenches of the plurality of active cell trenches of the active cell region confine first mesa regions, and wherein the semiconductor substrate region is electrically isolated from the first mesa regions.

Example 20: The semiconductor device of any of the preceding examples, wherein neighboring active cell trenches of the plurality of active cell trenches of the active cell region confine first mesa regions having a first width, and wherein neighboring capacitance trenches of the plurality of capacitance trenches confine second mesa regions having a third width that is less than the first width.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A semiconductor device, comprising:
a semiconductor substrate;
an active cell region comprising a plurality of active cell trenches extending from a first main surface of the semiconductor substrate into the semiconductor substrate;
a sensor region comprising a sensor device;
a sensor pad formed over the first main surface of the semiconductor substrate and electrically connected to a first terminal of the sensor device;
a semiconductor substrate region of the semiconductor substrate formed below the sensor pad; and
a plurality of capacitance trenches formed below the sensor pad and extending from the first main surface of the semiconductor substrate into or through the semiconductor substrate region,
wherein one of a capacitance electrode formed in one of the plurality of capacitance trenches or the semiconductor substrate region is electrically connected to the sensor pad and forms a first electrode of an input capacitance.

2. The semiconductor device of claim 1, wherein the other one of the capacitance electrode formed in one of the plurality of capacitance trenches or the semiconductor substrate region forms a second electrode of the input capacitance.

3. The semiconductor device of claim 1, wherein the active cell trenches have at least one of a same width or a same depth as the plurality of capacitance trenches.

4. The semiconductor device of claim 1, wherein the active cell region comprises a plurality of active cells, and wherein a region below the sensor pad is devoid of active cells.

5. The semiconductor device of claim 1, wherein the active cell region comprises:
a source/emitter region formed at the first main surface of the semiconductor substrate; and
a drain/collector region formed at a second main surface of the semiconductor substrate opposite the first main surface, and
wherein the semiconductor device further comprises:
a source/emitter pad formed over the first main surface of the semiconductor substrate and electrically connected to the source/emitter region; and
a gate pad formed over the first main surface of the semiconductor substrate and electrically connected to gate electrodes formed in at least some of the plurality of active cell trenches of the active cell region.

6. The semiconductor device of claim 1, wherein the sensor region comprises a temperature sensor device configured to allow for a measurement of a temperature of the semiconductor device.

7. The semiconductor device of claim 6, wherein the temperature sensor device comprises at least one of a resistor and a plurality of diodes coupled in series.

8. The semiconductor device of claim 6, further comprising:
a further sensor pad formed over the first main surface of the semiconductor substrate and electrically connected to a second terminal of the temperature sensor device;
a further semiconductor substrate region of the semiconductor substrate formed below the further sensor pad; and
a plurality of further capacitance trenches formed below the further sensor pad and extending from the first main surface of the semiconductor substrate into or through the further semiconductor substrate region,
wherein at least one of a capacitance electrode formed in one of the plurality of further capacitance trenches or the further semiconductor substrate region is electrically connected to the further sensor pad and forms a first electrode of a further input capacitance.

9. The semiconductor device of claim 1, wherein the sensor region comprises a current sensor device configured to allow for a measurement of a current in the sensor region.

10. The semiconductor device of claim 9, wherein the current sensor device comprises a plurality of source/emitter regions formed at the first main surface of the semiconductor substrate and electrically connected to the sensor pad.

11. The semiconductor device of claim 9, wherein the sensor region comprises a temperature sensor device configured to allow for a measurement of a temperature of the semiconductor device, and wherein the current sensor device comprises:
a plurality of current sensor cell trenches extending from the first main surface of the semiconductor substrate into the semiconductor substrate, wherein gate electrodes formed in at least some of the plurality of current sensor cell trenches of the current sensor device are electrically connected to the gate pad; and
a drain/collector region formed at a second main surface of the semiconductor substrate opposite the first main surface and electrically connected to the drain/collector region of the active cell region.

12. The semiconductor device of claim 9, wherein the sensor region comprises a temperature sensor device configured to allow for a measurement of a temperature of the semiconductor device, and wherein the semiconductor device further comprises:
a plurality of capacitance electrodes formed in the plurality of capacitance trenches,
wherein at least one of the plurality of capacitance electrodes is electrically connected to one of the sensor pad, the gate pad or a source/emitter pad and forms the first electrode of the input capacitance.

13. The semiconductor device of claim 12, wherein a second capacitance electrode of the plurality of capacitance electrodes is electrically connected to another one of the sensor pad, the gate pad or the source/emitter pad and forms a first electrode of a second input capacitance.

14. The semiconductor device of claim 9, wherein the sensor region comprises a temperature sensor device configured to allow for a measurement of a temperature of the semiconductor device, and wherein the semiconductor device further comprises:
a plurality of capacitance electrodes formed in the plurality of capacitance trenches,
wherein a first capacitance electrode of the plurality of capacitance electrodes is electrically connected to the sensor pad and forms the first electrode of the input capacitance,
wherein a further capacitance electrode of the plurality of capacitance electrodes is electrically connected to a source/emitter pad and forms a first electrode of a further input capacitance, and
wherein a third capacitance electrode of the plurality of capacitance electrodes is electrically connected to the gate pad and forms a first electrode of a third input capacitance.

15. The semiconductor device of claim 1, wherein the capacitance trenches extend in parallel along the first main surface of the semiconductor substrate, and
wherein at least one of the capacitance trenches extends uninterrupted into the active cell region.

16. The semiconductor device of claim 1, wherein the capacitance trenches extend in parallel along the first main surface of the semiconductor substrate, and
wherein neighboring ones of the capacitance trenches are connected to each other via an intersecting trench that extends transverse to the plurality of capacitance trenches.

17. The semiconductor device of claim 1, wherein the semiconductor substrate region is electrically connected to the sensor pad.

18. The semiconductor device of claim 1, wherein the active cell region comprises:
a source/emitter region formed at the first main surface of the semiconductor substrate,
wherein the semiconductor device further comprises:
a source/emitter pad formed over the first main surface of the semiconductor substrate and electrically connected to the source/emitter region,
wherein the semiconductor substrate region is electrically connected to the source/emitter pad.

19. The semiconductor device of claim 1, wherein the plurality of capacitance trenches is formed separately from the sensor device.

20. The semiconductor device of claim 1, wherein the semiconductor substrate region comprises:
a first part; and
a second part that is electrically isolated from the first part,
wherein the first part comprises a body region, and
wherein the second part comprises a deep well region that extends deeper into the semiconductor substrate than the body region.

21. The semiconductor device of claim 1, wherein neighboring ones of the active cell trenches of the active cell region confine first mesa regions, and wherein the semiconductor substrate region is electrically isolated from the first mesa regions.

22. The semiconductor device of claim 1, wherein neighboring ones of the active cell trenches of the active cell region confine first mesa regions having a first width, and
wherein neighboring ones of the capacitance trenches confine second mesa regions having a third width that is less than the first width.
